(19) United States
(12) Patent Application Publication
(10) Pub. No.: US 2010/0315078 A1
(43) Pub. Date: Dec. 16, 2010

(54) METHOD FOR EVALUATING ELECTRODE MATERIAL, METHOD FOR PRODUCING ELECTRODE, AND APPARATUS FOR PRODUCING ELECTRODE

(76) Inventors: Mitsuhiro Takeno, Osaka (JP); Masakazu Yamada, Osaka (JP)

Correspondence Address: MCDERMOTT WILL & EMERY LLP, 600 13TH STREET, NW, WASHINGTON, DC, 20005-3096, US

(21) Appl. No.: 12/744,035

(22) PCT Filed: Dec. 12, 2008
(86) PCT No.: PCT/JP2008/003737

§ 371 Date: May 20, 2010

(30) Foreign Application Priority Data
Dec. 14, 2007 (JP) 2007-322794
Dec. 11, 2008 (JP) 2008-315725

(51) Int. Cl. G01R 33/12

(52) U.S. Cl. 324/239

(57) ABSTRACT

A method for evaluating an electrode material for a non-aqueous electrolyte secondary battery including the steps of: (A) vibrating an electrode material for a non-aqueous electrolyte secondary battery at a prescribed frequency successively in two or more levels of magnetic fields that have different magnetic flux densities; (B) detecting induced magnetizations that are synchronous with the vibrations generated in the electrode material; and (C) determining saturation magnetization of the electrode material from the induced magnetizations.

### TECHNICAL FIELD

The present invention relates to a method for evaluating an electrode material for a non-aqueous electrolyte secondary battery, and a method and apparatus for producing an electrode for a non-aqueous electrolyte secondary battery, and more particularly to the detection of impurities contained in an electrode for a non-aqueous electrolyte secondary battery.

### BACKGROUND ART

Non-aqueous electrolyte secondary batteries include a positive electrode, a negative electrode, a separator interposed between the positive electrode and the negative electrode, and a non-aqueous electrolyte. The positive electrode includes a positive electrode active material containing a lithium transition metal composite oxide such as lithium cobalt oxide, and the negative electrode includes a negative electrode active material such as a graphite material. The separator has a function of electronically insulating the positive electrode and the negative electrode from each other, as well as a function of retaining the non-aqueous electrolyte. Non-aqueous electrolyte secondary batteries, in particular, lithium ion secondary batteries mostly employ microporous polyethylene resin films as separators.

In the production process of such positive and negative electrodes, the electrode material is passed through a large number of mechanically-operated equipments. During the production, there is a possibility that unwanted impurities might enter, even in a small amount, the electrode material due to the friction caused by mechanical operations. For example, if a metallic impurity enters the positive electrode, the impurity is ionized at the potential of the positive electrode and dissolved into the non-aqueous electrolyte. In such a state, the impurity might be deposited onto the negative electrode due to the potential gradient in the battery.

As the amount of metal deposited on the negative electrode increases, so-called dendrites grow. If dendrites grow through the separator and reach the positive electrode, a short-circuit occurs between the positive and negative electrodes, causing a reduction in the voltage and capacity of the battery. Accordingly, it is required to provide a clean production environment that can eliminate the incorporation of impurities into the electrode material to the greatest degree possible. However, it is difficult to completely eliminate the incorporation of impurities due to friction as long as electrodes are produced through mechanical operations.

In view of the above, various methods are considered to detect impurities that have entered the electrode material. For example, Patent Document 1 proposes a method in which metal impurities incorporated in a slurry containing a positive electrode material are detected by using a magnet.

Patent Document 2 proposes the use of an apparatus that detects magnetic disturbance by using magneto-impedance effect, specifically, an apparatus that generates magnetic disturbance in an electrode material for a lithium secondary battery that has been formed into a thin layer.

Patent Document 1: Japanese Laid-Open Patent Publication No. 2002-358952

Patent Document 2: Japanese Laid-Open Patent Publication No. 2005-183142

### DISCLOSURE OF THE INVENTION

### Problem to be Solved by the Invention

With the method disclosed in Patent Document 1, it is difficult to detect impurities with low magnetic susceptibility. Stainless steel, for example, has low magnetic susceptibility, so it does not sufficiently attract to a magnet. Accordingly, the method of Patent Document 1 cannot detect impurities such as a small amount of impurities of low magnetic susceptibility that has been attached to an active material and complexed.

The apparatus disclosed in Patent Document 2 measures the magneto-impedance of an electrode and detects a phenomenon in which the magneto-impedance is disturbed by the impurities. However, an electrode material is an aggregation of particles that have various distributions, and in some cases, the electrode material itself includes a paramagnetic substance. For example, nickel-containing lithium composite oxide itself is paramagnetic. In addition, with the method disclosed in Patent Document 2, in principle, a geomagnetic fluctuation, a disturbance in the magnetic field generated by a magnetic substance near the measurement apparatus or by the power source, and the like are detected. Thus, errors may occur in the result of measurement.

The present invention has been conceived to solve the above problems, and it is an object of the present invention to suppress a reduction in the production yield of electrodes to the greatest degree possible by measuring impurities (metal impurities) contained in electrode material.

### Means for Solving the Problem

The present invention relates to a method for evaluating an electrode material for a non-aqueous electrolyte secondary battery including the steps of: (A) vibrating an electrode material for a non-aqueous electrolyte secondary battery at a prescribed frequency successively in two or more levels of magnetic fields that have different magnetic flux densities; (B) detecting induced magnetizations that are synchronous with the vibrations generated in the electrode material; and (C) determining saturation magnetization of the electrode material from the induced magnetizations.

The amount of ferromagnetic impurities contained in the electrode material can be estimated from the saturation magnetization.

The step A includes, for example, vibrating the electrode material in magnetic fields having magnetic flux densities that are induced continuously over time.

The prescribed frequency is preferably 65 to 95 Hz.

According to a preferred embodiment, the evaluation method of the present invention further includes comparing the saturation magnetization with a prescribed threshold value and determining the electrode material as defective when the saturation magnetization exceeds the threshold value.

The prescribed threshold value is preferably a value per unit weight of the electrode material: 2.0×10⁻³ emu/g or less.

The step A may include vibrating an electrode for a non-aqueous electrolyte secondary battery in magnetic fields. In this case, the electrode includes a current collector and an active material layer attached to the current collector, and the active material layer includes the electrode material.

The present invention is effective particularly when the electrode material contains a composite oxide of lithium and a transition metal, and the transition metal includes at least one selected from the group consisting of Co, Ni and Mn, or at least one selected from the group consisting of a carbon material, Si and Sn. When the electrode material contains at least one transition metal selected from the group consisting of Co, Ni and Mn, the threshold value is preferably 1.0×10⁻³ emu/g or less. When the electrode material contains at least one selected from the group consisting of a carbon material, Si and Sn, the threshold value is preferably 2.0×10⁻³ emu/g or less.

The present invention also relates to a method for producing an electrode including the steps of:

(a) producing an electrode that includes a current collector and an active material layer attached to the current collector;

(b) vibrating the electrode at a prescribed frequency successively in two or more levels of magnetic fields that have different magnetic flux densities;

(c) detecting induced magnetizations that are synchronous with the vibrations generated in the active material layer;

(d) determining saturation magnetization of the active material layer from the induced magnetizations; and

(e) comparing the saturation magnetization with a prescribed threshold value and determining the electrode as defective when the saturation magnetization exceeds the threshold value.

In the above production method, there is no particular limitation on the kinds of electrode. The above production method is also applicable to an electrode for a non-aqueous electrolyte secondary battery, an electrode for an alkaline storage battery, and so on. The electrode for an alkaline storage battery may be either a negative electrode containing a hydrogen storage alloy or a positive electrode containing a nickel compound.

The present invention further relates to a electrode production apparatus including:

a pair of magnetic poles that have primary surfaces disposed facing each other and that are capable of generating two or more levels of magnetic fields that have different magnetic flux densities;

an electrode feed section that is disposed between the pair of magnetic poles;

a vibrator that vibrates an electrode that has been introduced into the electrode feed section at a prescribed frequency, the electrode including a current collector and an active material layer attached to the current collector;

a detector that detects induced magnetizations that are synchronous with the vibrations generated in the active material layer;

a computing unit that calculates saturation magnetization of the active material layer from the induced magnetizations detected by the detector; and

a determination unit that compares the saturation magnetization with a prescribed threshold value, and determines the electrode as defective when the saturation magnetization exceeds the threshold value.

### EFFECT OF THE INVENTION

All substances, when placed in a magnetic field, generate induced magnetization. When a substance is vibrated in a magnetic field, the induced magnetization varies in synchronization with the vibrations. Induced magnetization is generated in any of ferromagnetic, paramagnetic and diamagnetic substances, but ferromagnetic substances have a prescribed residual magnetization (saturation magnetization).

The present invention utilizes such properties of ferromagnetic substances. Because induced magnetization is synchronous with the vibrations applied to the electrode material, by selecting a vibration frequency, it is possible to easily eliminate the influence of geomagnetism and the power source of the device on the magnetization. Accordingly, the present invention is effective even when impurities are a metal that has low magnetic susceptibility such as stainless steel. The induced magnetization can be detected by using a high precision detector such as a hall element. Therefore, according to the present invention, it is possible to estimate the amount of ferromagnetic impurities that are present in the electrode material or electrode.

Even when the electrode material itself is non-defective, the resulting electrodes may be defective due to the incorporation of impurities during the production process. Accordingly, it is desired to separate such defective electrodes from non-defective electrodes by determining defect in the form of the paste or electrode. According to the present invention, it is possible to determine the presence or absence of impurities, that can cause insufficient voltage, during the electrode production process (in the form of the paste or electrode). Therefore, a reduction in the production yield of batteries can be effectively suppressed.

### BRIEF DESCRIPTION OF THE DRAWINGS

FIG. 1 is a diagram showing the relationship between magnetic field intensity and magnetization of Sample 1 according to an example.

FIG. 2 is a diagram showing the relationship between magnetic field intensity and magnetization of Sample 2 according to an example.

FIG. 3 is a diagram showing a process for determining saturation magnetization from FIG. 2.

FIG. 4 is a diagram showing the relationship between magnetic field intensity and magnetization of Sample 3 according to an example.

FIG. 5 is a diagram showing the relationship between magnetic field intensity and magnetization of Sample 4 according to an example.

FIG. 6 is a top plan view schematically showing the structure of a production apparatus according to the present invention.

FIG. 7 is a front view schematically showing the structure of the production apparatus according to the present invention.

### BEST MODE FOR CARRYING OUT THE INVENTION

An evaluation method according to the present invention includes the steps of: (A) vibrating an electrode material for a non-aqueous electrolyte secondary battery (hereinafter sometimes referred to simply as an “electrode material”) in magnetic fields; (B) detecting induced magnetizations that are synchronous with the vibrations; and (C) determining saturation magnetization of the electrode material from the induced magnetizations.

In the step A, the electrode material is vibrated at a prescribed frequency successively in two or more levels of magnetic fields that have different magnetic flux densities.

For example, the electrode material is vibrated at a prescribed frequency successively in a magnetic field having a first magnetic flux density (B₁) and a magnetic field having a second magnetic flux density (B₂, where B₂≠B₁). In this situation, an induced electromotive force that is synchronous with the vibrations of the electrode material is generated according to each of the magnetic flux densities. By the induced electromotive force, induced magnetization that is synchronous with the vibrations of the electrode material is generated.

In the step A, the electrode material may be vibrated in magnetic fields having magnetic flux densities that are continuously induced over time. This enables more accurate measurement of the saturation magnetization of the electrode material. Specifically, the magnetic flux density of the magnetic field is decreased over time while measuring the induced magnetization that has occurred in the vibrating electrode material so as to temporarily zero the magnetic field. After that, a magnetic field of opposite direction is applied to the electrode material. When a magnetic field of opposite direction is applied to the electrode material, an induced magnetic field in the opposite vector direction is generated from ferromagnetic substances (impurities) contained in the electrode material or paramagnetic substances (the electrode material, the current collector and so on).

In the step B, induced magnetizations that are synchronous with the vibrations generated in the electrode material are detected. A magnetic field due to each of the induced magnetizations can be quantitatively detected by using, for example a hall element. The hall element is an element that detects magnetic fields by utilizing the Hall effect. By disposing a hall element near the electrode material, induced magnetizations that are synchronous with the vibrations can be detected. Thus, lines of magnetic force that are not synchronous with the vibrations, or in other words, lines of magnetic force that are not due to the magnetization of the electrode material can be eliminated.

In the step C, the saturation magnetization of the electrode material is determined from the detected induced magnetizations. Specifically, the relationship between the amounts of magnetizations due to the induced magnetizations detected in the step B and the magnetic flux densities applied to the electrode material is plotted. Note that the electrode material and the current collector are usually either paramagnetic or diamagnetic, and impurities are mostly ferromagnetic. The magnetization M of a ferromagnetic substance is represented by M=χ₁×m₁×H+σ×m₁, where H (Oe) is magnetic field intensity, m₁ (g) is the mass of the ferromagnetic substance, χ₁ is the magnetic susceptibility of the ferromagnetic substance, and σ is the saturation magnetic susceptibility of the ferromagnetic substance. The saturation magnetic susceptibility σ is uniquely determined by the kinds of a ferromagnetic substance. In other words, the magnetization M of a ferromagnetic substance will not be zero even when the magnetic field intensity H is zero, and σ×m₁ remains as residual magnetization (saturation magnetization).

On the other hand, the magnetization of a paramagnetic substance and that of a diamagnetic substance vary in proportion to the magnetic flux density. The magnetization M of a paramagnetic substance or diamagnetic substance is expressed by M=χ₂×m₂×H, where H (Oe) is magnetic field intensity, χ₂ is the magnetic susceptibility of the paramagnetic substance or diamagnetic substance, and m₂ (g) is the mass of the paramagnetic substance or diamagnetic substance. χ₂ takes a positive value in the case of a paramagnetic substance, and χ₂ takes a negative value in the case of a diamagnetic substance. When the magnetic field intensity H is zero, the magnetization M of a paramagnetic substance or diamagnetic substance will also be zero.

For example, the magnetization M of an electrode containing impurities is expressed by M=(χₚmₚ+χ_{d}m_{d}+χ_{f}m_{f})×H+σ×m_{f}, where χₚ, χ_{d} and χ_{f} are the magnetic susceptibility of a paramagnetic substance, a diamagnetic substance and a ferromagnetic, substance (impurities), respectively; mₚ, m_{d} and m_{f} are the masses of the paramagnetic substance, the diamagnetic substance and the ferromagnetic substance (impurities), respectively. As described above, the magnetization of a paramagnetic substance or diamagnetic substance is zero when H=0. Accordingly, by determining the amount of magnetization of the electrode when H=0, the magnetizations of the electrode material and the current collector are eliminated, and the saturation magnetization of impurities (ferromagnetic substance) can be obtained.

The saturation magnetization of the ferromagnetic substance can be obtained by extrapolating a plot showing the relationship between induced magnetizations and magnetic field intensities to H=0. Specifically, induced magnetization that is synchronous with the vibrations of the electrode material is measured in each of a magnetic field having a first magnetic flux density and a magnetic field having a second magnetic flux density, and the relationship between the amounts of magnetizations due to the induced magnetizations and the magnetic fields is plotted at two points. The amount of magnetization obtained at the intersection of the straight line connecting the two points and the line representing H=0 corresponds to the saturation magnetization of the ferromagnetic substance. It is sufficient to plot two points, but it is better to plot more points, and it is desirable to continuously obtain changes in the induced magnetizations by vibrating the electrode material in a magnetic field whose magnetic flux density is continuously changed.

Simultaneous equations are obtained by measuring magnetization M in each of a magnetic field having a first magnetic flux density and a magnetic field having a second magnetic flux density, and substituting the measured values into the relationship expression between magnetization M and magnetic field H. By solving the equations, the value of saturation magnetization (σ×m) can be obtained. By dividing the saturation magnetization by the mass (m), saturation magnetic susceptibility (σ) can be obtained. The saturation magnetic susceptibility of a ferromagnetic substance is proportional to the saturation magnetization of the electrode material per unit weight. Accordingly, in the present invention, saturation magnetization may be converted to saturation magnetic susceptibility and used. From the saturation magnetic susceptibility and the weight of the electrode material, the amount of impurities (ferromagnetic substance) contained in the electrode material can be estimated.

When the saturation magnetic susceptibility σ exceeds a prescribed threshold value, the electrode material is determined as defective. On the other hand, when the saturation magnetic susceptibility is the prescribed threshold value or less, the local formation of dendrites due to the ferromagnetic substance dissolved from the electrode into the electrolyte can be suppressed. Accordingly, the reduction in the voltage and capacity of the battery can be suppressed.

In the present invention, the electrode material may be a positive electrode material or negative electrode material. In the case of a positive electrode material containing ferromagnetic impurities, when the potential of the positive electrode becomes high during charge, the impurities are dissolved at a high speed and deposited onto the negative electrode. Accordingly, care needs to be taken especially for positive electrode material not to include impurities.

The evaluation method of the present invention is also applicable to an electrode material powder for a non-aqueous electrolyte secondary battery, as well as to a paste containing an electrode material and optional components such as a binder. The evaluation method of the present invention is also applicable to an electrode that includes a current collector and an active material layer attached to the current collector, the active material layer containing an electrode material.

The prescribed threshold value can be, for example, 1.0×10⁻³ emu/g or less (per unit weight of the electrode material). This is because a ferromagnetic substance in an amount corresponding to a saturation magnetization of 1.0×10⁻³ emu/g or less does not affect the characteristics of the battery. Although the smaller amount of ferromagnetic impurities is more preferable, it is considered that the local formation of dendrites due to a ferromagnetic substance does not occur when the amount is extremely small.

The present invention is particularly effective when the electrode material contains a lithium transition metal composite oxide, and the lithium transition metal composite oxide contains at least one selected from the group consisting of Co, Ni and Mn. Such lithium transition metal composite oxides are useful as positive electrode materials for non-aqueous electrolyte secondary batteries. For example, lithium cobalt oxide is diamagnetic, and a lithium transition metal composite oxide in which part of the cobalt has been substituted by nickel and a spinel lithium manganese composite oxide are paramagnetic. Accordingly, by applying the present invention to any of these electrode materials, it is possible to easily detect ferromagnetic impurities.

The present invention is also particularly effective when the electrode material contains at least one selected from the group consisting of a carbon material, Si and Sn. In this case, the threshold value is preferably 2.0×10⁻³ emu/g or less. Such electrode materials are useful as negative electrode materials for non-aqueous electrolyte secondary batteries. A carbon material, Si, Sn, an alloy of Si and lithium, an alloy of Sn and lithium are diamagnetic. Accordingly, by applying the present invention to any of these electrode materials, it is possible to easily detect ferromagnetic impurities.

The present invention is also applicable to a case where an electrode is vibrated in magnetic fields. In this case, the electrode includes a current collector and an active material layer attached to the current collector, the active material containing an electrode material. For example, a carbon material as a conductive material, a polymer compound as a binder and aluminum or the like as a current collector that are used in a positive electrode for a non-aqueous electrolyte secondary battery are diamagnetic. Likewise, a polymer compound as a binder, a thickener and a copper foil or the like as a current collector that are used in a negative electrode for a non-aqueous electrolyte secondary battery are diamagnetic. Accordingly, ferromagnetic impurities can be easily detected even when the present invention is applied to electrodes.

There is no particular limitation on the method for generating magnetic fields, but it is preferable to use an electromagnet with a lorentz coil. When generating two or more levels of magnetic fields that have different magnetic flux densities, it is only necessary to feed currents to the electromagnet with two different current values or more. When continuously changing the magnetic flux densities of magnetic fields, it is only necessary to continuously change the current value fed to the electromagnet.

When the electrode material is vibrated in a prescribed magnetic field at a prescribed frequency, induced magnetization that is synchronous with the vibration frequency is generated. The induced magnetization is uniquely determined by the magnetic susceptibility of the material used. Because the induced magnetization is synchronous with the vibrations of the electrode material, by selecting a vibration frequency as appropriate, the influence of geomagnetism and the power source of the device on the magnetization can be eliminated. This significantly improves the precision of detection of lines of magnetic force due to the induced magnetization, and consequently the precision of measurement of the amount of magnetization.

Geomagnetism has an extremely low, fluctuating frequency. Accordingly, the influence of geomagnetic can be eliminated by vibrating the electrode material at a frequency of, for example, several tens of hertz or more. There is no particular limitation on the frequency used to vibrate the electrode material, but the frequency is preferably, for example, 65 to 95 Hz. Commercial power sources have a frequency of 50 Hz or 60 Hz, so when the electrode material is vibrated at such a frequency, the magnetization may be affected by the power source. When the electrode material is vibrated at a frequency of 100 Hz, 150 Hz, 120 Hz or the like, there is a concern that there may be an influence of higher harmonics of the commercial power source. From the viewpoint of preventing damage to the electrode and the electrode material, it is preferable that the frequency does not exceed 200 Hz.

There is no particular limitation on the apparatus for measuring the induced magnetization of the electrode material, it is preferable to use a VSM (vibrating sample magnetometer). The VSM can measure even a very small amount of magnetization as small as an amount of magnetization of about 10⁻⁶ emu/g. The VSM is an apparatus that vibrates a sample in a magnetic field at a constant frequency and amplitude, and measures the magnetization of the sample. A sample for impurity detection is vibrated in a measurement section of the vibrating sample magnetometer, and magnetic fields are applied to the sample. When the electrode material contains a ferromagnetic substance as impurities, lines of magnetic force synchronous with the vibrations are generated.

Next, an apparatus for producing an electrode according to the present invention will be described. The production apparatus includes a pair of magnetic poles that have primary surfaces disposed facing each other and that are capable of generating two or more levels of magnetic fields that have different magnetic flux densities. The pair of magnetic poles each can be made up of a lorentz coil. An electrode feed section is provided between the pair of magnetic poles, or in other words, between the primary surfaces that are disposed facing each other. Into the electrode feed section, for example, an electrode that is unfinished and still under production or an electrode in the final stage of the production process is introduced. For example, a roll-shaped electrode before cut to a prescribed shape is continuously fed to the electrode feed section. At this time, a vibrator provided in the apparatus is brought into contact with part of the electrode, the position of the vibrator is fixed, and the electrode is conveyed to successively move the contact portion. In this manner, vibrations of a prescribed frequency are continuously applied to the electrode.

A detector that detects induced magnetizations generated in the active material layer by vibrations is provided near the electrode, and the detector is in communication with a computing unit. The induced magnetizations synchronous with the vibrations of the electrode that were detected by the detector are sent to the computing unit, where saturation magnetization due to a ferromagnetic substance is calculated. The saturation magnetization calculated in the computing unit is sent to a determination unit, where the saturation magnetization is compared with a prescribed threshold value. The prescribed threshold value has been stored in a prescribed storage unit. When the saturation magnetization exceeds the threshold value, the determination unit determines the electrode as defective and emits a prescribed signal.

By using such a production apparatus described above, it is possible to continuously detect impurities contained in the electrode in the electrode production process. The weight of the electrode material contained in an electrode is a given value that is determined by the design specifications of the battery, so the saturation magnetization of the electrode material can be easily calculated. By comparing the obtained saturation magnetization with a prescribed threshold value in the determination unit one after another, it is possible to continuously and rapidly determine defective electrodes.

A specific example of the production apparatus of the present invention will be described with reference to the drawings.

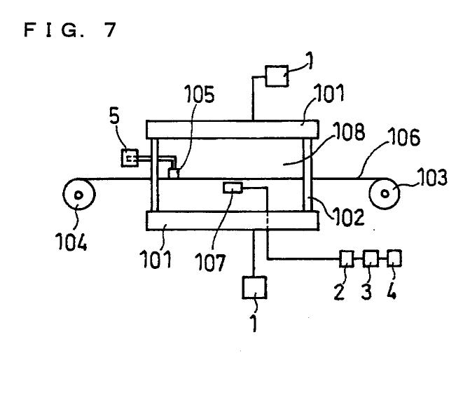

FIGS. 6 and 7 are a top plan view and a front view schematically showing an electrode production apparatus according to an embodiment of the present invention.

A pair of magnetic poles 101 housing lorentz coils are disposed such that their primary surfaces face each other. Each magnetic pole 101 is connected to a power source unit 1, and a current at an arbitrary current value is applied to the magnetic poles 101 from the power source unit 1. Four posts 102 are provided between the pair of magnetic poles 101 to form an electrode feed section 108. In the electrode feed section 108, a magnetic field of a prescribed magnetic flux density is formed. From the viewpoint of reducing the disturbance of the magnetic field in the electrode feed section 108, the posts 102 are preferably made of a material that is nonmagnetic and has superior durability such as bakelite.

An electrode 106 is continuously or intermittently supplied from a hoop supplier 103 to the electrode feed section 108. A hoop winder 104 winds the electrode 106 after impurity detection. A vibrator 105 connected to a function generator 5 is disposed such that it comes into contact with the electrode 106 constantly or cyclically. A hall element 107 for detecting induced magnetizations that is synchronous with the vibrations of the electrode is disposed near the electrode. The hall element 107 is connected to a computing unit 2, a determination unit 3 and a display unit 4. The display unit 4 displays the result obtained from the determination unit 3.

When a direct current is applied from the power source unit 1 to the lorentz coils of the magnetic poles 101, a magnetic field is formed in the electrode feed section 108. By successively applying direct currents having two or more current values from the power source unit 1, two or more levels of magnetic fields can be generated successively. Alternatively, by continuously changing the direct currents applied to the lorentz coils, the magnetic flux density of the magnetic field induced in the electrode feed section can be continuously changed.

It is preferable that the lorentz coils have a diameter larger than the length in the widthwise direction of the electrode. Usually, lorentz coils having a diameter of about 10 cm are used to measure magnetization with a VSM. However, in the present invention, it is preferable to use lorentz coils that are capable of forming magnetic fields having an area of, for example, 2400 cm² or more (e.g., a size of 60 cm×40 cm or more), and the primary faces of the magnetic poles 101 preferably have an area of 2400 cm² or more (e.g., 60 cm×40 cm or more), whereby magnetic fields can be generated uniformly in the widthwise direction of the electrode.

Usually, a pair of lorentz coils are disposed perpendicular to the ground when measuring magnetization with a VSM. However, with the production apparatus of the present invention, large-format lorentz coils are disposed such that the primary surfaces of the pair of magnetic poles 101 are perpendicular to the direction of gravity, whereby it is possible to increase the installation stability of the large-format lorentz coils, as well as reducing the variations in magnetic flux density within the coils. Such a configuration enables the electrode 106 to travel in the horizontal direction, as well as enabling easy supplying and winding of the electrode.

In large-format lorentz coils, the resistance values of the copper wires used in the coils are large. Accordingly, it is desirable to use thick copper wires as thick as about 8 SQ in the production apparatus of the present invention. In the case where electrode evaluation is performed continuously for a long period of time, a water-cooling device or the like may be used in consideration of the heat generated from the lorentz coils. In this case, from the viewpoint of eliminating the influence of ferromagnetic impurities contained in cooling water, it is preferable to use super-pure water as a coolant. It is also preferable that the pipes and the pump are all made of a fluorocarbon resin.

The vibrator 105 vibrates in response to a signal from the function generator 5. The vibrator 105 is brought into contact with the electrode 106 to vibrate the electrode 106. There is no particular limitation on the frequency output from the function generator 5, but the frequency is preferably 65 to 95 Hz, for example.

There is a case where the electrode 106 includes an active material layer containing, for example, a lithium transition metal composite oxide, a conductive material, a binder and so on, and has a high weight per unit area, so it is difficult to vibrate the electrode 106. In such a case, for example, a speaker cone of about 200 W that exhibits superior performance in the low frequency region can be used as a vibrator. In this case, it is preferable to sufficiently increase the output of the function generator 5. When the output is insufficient, an A-B class amplifier may be connected between the function generator 5 and the vibrator 105.

The hall element 107 detects induced magnetizations that are synchronous with the vibrations of the electrode by utilizing the Hall effect. The data of induced magnetizations that were detected by the hall element 107 is sent to the computing unit 2, where saturation magnetization is calculated. The calculated saturation magnetization is sent to the determination unit 3, where the saturation magnetization is compared with a prescribed threshold value. When the saturation magnetization exceeds the prescribed threshold value, the electrode is determined as defective. When the saturation magnetization does not exceed the threshold value, the electrode is determined as non-defective. The result of determination by the determination unit 3 is output to the display unit 4.

### EXAMPLES

### Example 1

### Sample 1

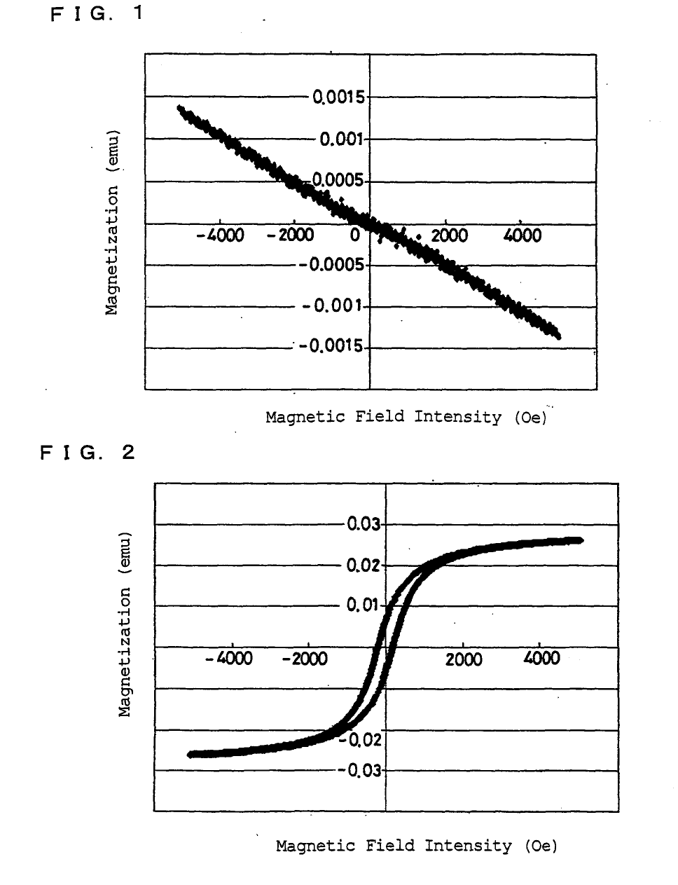

As a vibrating sample magnetometer, VSM-P7 available from Toei Industry Co., Ltd. was used. Lithium cobalt oxide (Cellseed (C) available from Nippon Chemical Industrial Co., Ltd.) as a sample for measurement was placed on an acrylic resin sample holder having a diameter of 7 mm and a thickness of 5 mm in an amount of 200 mg. Then, a magnetic field of 5000 Oe (oersted) was applied, and thereafter, the magnetic field H intensity was reduced to 0 in 5 minutes. The magnetic field was then reversed, and the magnetic field H was linearly increased to 5000 oersted in 5 minutes. After that, the magnetic field H intensity was reduced to 0 in 5 minutes, after which the magnetic field was reversed, and the magnetic field H was linearly increased to 5000 oersted in 5 minutes. The relationship between the magnetic field intensities at this time (horizontal axis) and the magnetizations measured with the vibrating sample magnetometer (vertical axis) is shown in FIG. 1.

In FIG. 1, a straight line inclined downward toward the right was obtained because the lithium cobalt oxide is diamagnetic, from which it can be seen that no ferromagnetic substance was contained in Sample 1.

### Sample 2

The relationship between magnetic field intensities and magnetizations (FIG. 2) was obtained in exactly the same manner as in the case of Sample 1, except that a sample for measurement obtained by adding 6.8 parts by weight of ferrite powder to 94 parts by weight of lithium cobalt oxide was used.

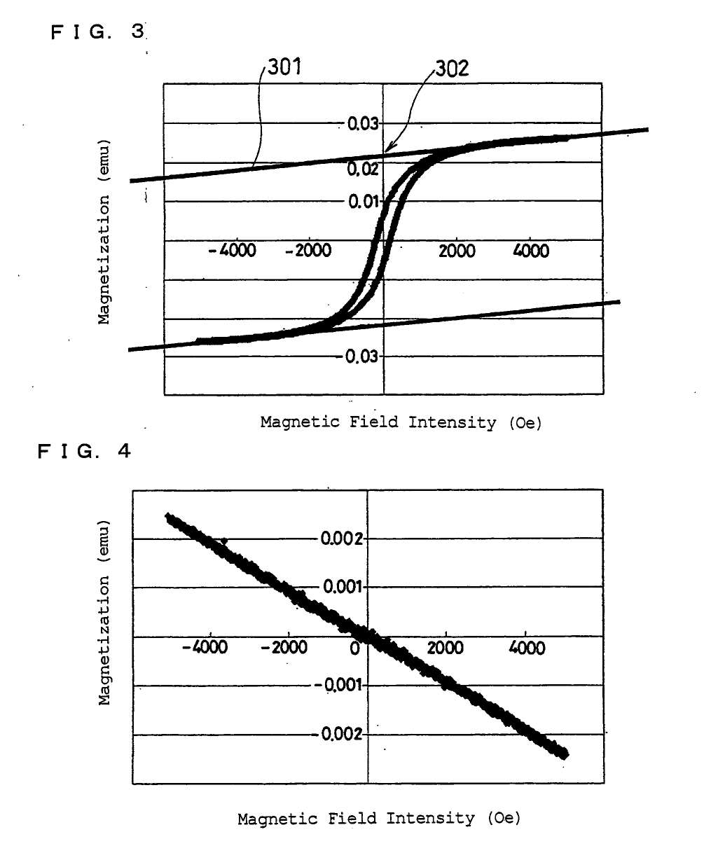

In FIG. 2, the magnetizations did not change linearly with respect to the magnetic fields, and thus a curve was obtained. This behavior indicates the presence of a ferromagnetic substance. By drawing a tangent 301 on the curve as shown in FIG. 3, the saturation magnetization of a ferromagnetic substance contained in the sample can be determined from an intercept 302 on the magnetization (vertical axis). From B=μ₀H+M, the magnetization M when the magnetic field intensity H is zero corresponds to magnetic flux density B. In the equation: M=(χₚmₚ+χ_{d}m_{d}+χ_{f}m_{f})×H+σ×m_{f}, by setting the magnetic field intensity H to 0 and the magnetization M to the value of the intercept 302, the saturation magnetization of the ferromagnetic substance can be determined.

It was found from the result that Sample 2 contained a ferromagnetic substance in an amount corresponding to a saturation magnetization of 0.022 emu. Because the weight of Sample 2 was 200 mg, 0.22 emu/g was obtained.

### Sample 3

The relationship between magnetic field intensities and magnetizations (FIG. 4) was obtained in exactly the same manner as in the case of Sample 1, except that a carbon material (Carbotron P available from Kureha Corporation) generally used as a negative electrode material for a non-aqueous electrolyte secondary battery was used as a sample for measurement instead of lithium cobalt oxide. It was found that Sample 3 was diamagnetic and no ferromagnetic substance was contained in Sample 3, as in Sample 1.

### Sample 4

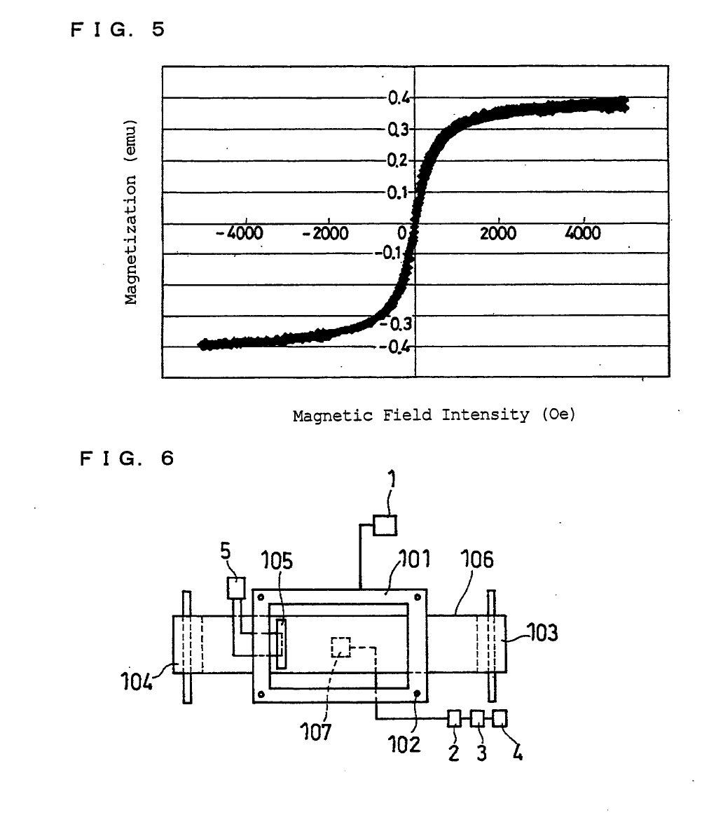

The relationship between magnetic field intensities and magnetizations (FIG. 5) was obtained in exactly the same manner as in the case of Sample 1, except that a ferrite powder, which is ferromagnetic, was used as a sample for measurement. As a result, a hysteresis curve characteristic of a ferromagnetic substance was obtained.

### Example 2

### Battery A

A positive electrode paste was obtained by mixing 1000 g of lithium cobalt oxide (Cellseed C) available from Nippon Chemical Industrial Co., Ltd. with 3 g of polyvinylidene fluoride (#1300) available from Kureha Corporation and 4 g of acetylene black (Denka Black) available from Denki Kagaku Kogyo K.K., and further mixing the resultant mixture with 2000 ml of N-methylpyrrolidinone available from Mitsubishi Chemical Corporation. The obtained paste was applied onto a 20 μm thick aluminum foil, rolled and cut. Then, an aluminum lead was attached thereto to obtain a positive electrode for a lithium secondary battery.

A negative electrode paste was obtained by mixing 1000 g of graphite material (KS-4) available from Timcal, U.S.A. with 3 g of polyvinylidene fluoride and 2000 ml of N-methylpyrrolidinone available from Mitsubishi Chemical Corporation. The obtained paste was applied onto a 20 μm thick copper foil, which was rolled and cut. Then, a nickel lead was attached thereto to obtain a negative electrode for a lithium secondary battery.

The obtained positive electrode and negative electrode were spirally wound with a 27 μm thick separator available from Tonen Chemical Corporation interposed therebetween to form an electrode group, and the electrode group was inserted into an iron battery case having a diameter of 18 mm and a height of 650 mm. After that, a non-aqueous electrolyte solution available from Mitsubishi Chemical Corporation was injected into the battery case to impregnate the electrode group. In the used non-aqueous electrolyte solution, lithium hexafluorophosphate was dissolved, at a concentration of 1.0 mol/L, in a solvent of ethylene carbonate and diethyl carbonate mixed at a volume ratio of 1:1. Then, the battery case was sealed to obtain a 2000 mAh battery. Twenty similar batteries were produced. Each battery was charged to 4.2 V, and left at 600 for 24 hours, and the voltage after 24 hours was measured. The results are shown in Table 1.

Before forming an electrode group, the positive electrode was subjected to a vibrating sample magnetometer to measure the amount of a ferromagnetic substance, and found to contain a ferromagnetic substance in an amount corresponding to 1.0×10⁻³ emu/g.

### Battery a

Twenty batteries were produced and the voltage after 24 hours was measured similar to the case of Battery A, except that 1 g of metal nickel powder available from Kojundo Chemical Lab. Co., Ltd. was added to 1000 g of lithium cobalt oxide. The results are shown in Table 1. In addition, before forming an electrode group, the positive electrode was subjected to a vibrating sample magnetometer to measure the amount of a ferromagnetic substance, and found to contain a ferromagnetic substance in an amount corresponding to 1.5×10⁻³ emu/g.

### Battery b

Twenty batteries were produced and the voltage after 24 hours was measured in the same manner as Battery A, except that 2 g of metal nickel powder available from Kojundo Chemical Lab. Co., Ltd. was added to 1000 g of lithium cobalt oxide. The results are shown in Table 1. In addition, before forming an electrode group, the positive electrode was subjected to a vibrating sample magnetometer to measure the amount of a ferromagnetic substance, and found to contain a ferromagnetic substance in an amount corresponding to 3.0×10⁻³ emu/g.

### Battery c

Twenty batteries were produced and the voltage after 24 hours was measured in the same manner as Battery A, except that 10 g of metal nickel powder available from Kojundo Chemical Lab. Co., Ltd. was added to 1000 g of lithium cobalt oxide. The results are shown in Table 1. In addition, before forming an electrode group, the positive electrode was subjected to a vibrating sample magnetometer to measure the amount of a ferromagnetic substance, and found to contain a ferromagnetic substance in an amount corresponding to 0.5 emu/g.

TABLE 1

Voltage after 24 hrs. (V)

| | Battery A | Battery a | Battery b | Battery c |
|---|---|---|---|---|
| 1 | 4.15 | 3.69 | 4.15 | 4.15 |
| 2 | 4.12 | 3.44 | 4.11 | 4.12 |
| 3 | 4.15 | 3.80 | 3.28 | 4.11 |
| 4 | 4.19 | 2.08 | 4.12 | 4.19 |
| 5 | 4.16 | 3.69 | 4.15 | 4.09 |
| 6 | 4.15 | 3.89 | 4.15 | 4.09 |
| 7 | 4.11 | 3.25 | 4.19 | 3.99 |
| 8 | 4.19 | 3.57 | 3.98 | 4.08 |
| 9 | 4.16 | 4.15 | 4.05 | 4.10 |
| 10 | 4.15 | 3.63 | 3.68 | 4.19 |
| 11 | 4.19 | 3.79 | 4.19 | 4.16 |
| 12 | 4.12 | 3.61 | 4.16 | 4.08 |
| 13 | 4.18 | 3.80 | 4.15 | 4.00 |
| 14 | 4.15 | 2.98 | 4.11 | 3.98 |
| 15 | 4.12 | 4.05 | 4.00 | 4.09 |
| 16 | 4.11 | 4.00 | 4.19 | 4.15 |
| 17 | 4.19 | 3.79 | 3.87 | 3.89 |
| 18 | 4.19 | 3.19 | 4.19 | 4.00 |
| 19 | 4.15 | 3.79 | 4.19 | 4.19 |
| 20 | 4.14 | 3.99 | 4.15 | 4.00 |

It can be seen from Table 1 that the battery voltage decreased when a ferromagnetic substance was contained in the positive electrode in an amount corresponding to 1.5×10⁻³ emu/g or more, and no voltage reduction was observed when a ferromagnetic substance was contained in an amount corresponding to 1.0×10⁻³ emu/g or less. This is presumably because when a ferromagnetic substance was contained in the positive electrode in an amount corresponding to 1.5×10⁻³ emu/g or more, the ferromagnetic substance was dissolved at the positive electrode and then deposited on the negative electrode, causing a partial internal short circuit.

### Example 3

### Electrode A

A positive electrode was produced by using the production apparatus shown in FIGS. 6 and 7. First, a positive electrode paste was obtained by mixing 90 parts by weight of Cellseed C available from Nippon Chemical Industrial Co., Ltd., 5 parts by weight of acetylene black available from Denki Kagaku Kogyo K.K., and 5 parts by weight of polyvinylidene fluoride (#1300) available from Kureha Corporation in N-methylpyrrolidinone available from Kanto Chemical Co., Inc. as a dispersing medium. The obtained paste was applied onto a 20 μm thick aluminum foil available from Showa Denko K.K., and dried to obtain a sample electrode 106 (6 cm wide, 20 m long) in the form of a hoop.

Next, the sample electrode 106 was continuously fed to the electrode feed section 108 of the production apparatus shown in FIGS. 6 and 7. The size of the primary surfaces of the pair of magnetic poles was 20 cm×20 cm. The magnetic flux density of the magnetic field in the electrode feed section was set such that the magnetic field intensity was switched every second between two levels: 5000 oersted and 2500 oersted. The power source unit 1 was set so as to cause the function generator 5 to provide a 70 Hz signal, and the signal was transmitted to the vibrator 105 to vibrate the sample electrode 106.

The output of the hall element 107 obtained by the computing unit 2 was checked, and it was found that the saturation magnetization was 2.7×10⁻⁵ emu/g. Because the threshold value of the determination unit 3 had been set to 1.0×10⁻³ emu/g in advance, the electrode was determined as non-defective, and thus “non-defective” was output to the display unit 4.

A cylindrical lithium secondary battery having a diameter of 18 mm and a height of 650 mm was produced by using the above positive electrode.

First, a negative electrode paste was prepared by mixing while stirring 95 parts by weight of artificial graphite (KS-6) available from Timcal Japan, 3 parts by weight of carboxymethyl cellulose, 3 parts by weight of styrene butadiene latex emulsion available from JSR Corporation, and water as a dispersing medium. The obtained paste was applied onto a 20 μm thick copper foil available from Nippon Denkai, Ltd., dried and rolled to obtain a negative electrode. Then, an electrode group was formed by interposing a 27 μm thick microporous polyethylene film available from Tonen Chemical Corporation as a separator between the positive electrode and the negative electrode. The electrode group was impregnated with a non-aqueous electrolyte solution available from Mitsubishi Chemical Corporation. In the used non-aqueous electrolyte solution, lithium hexafluorophosphate (available from Stella Chemifa Corporation) was dissolved, at a concentration of 1.5 mol/L, in a solvent mixture of ethylene carbonate and diethyl carbonate at a volume ratio of 1:1.

Five similar cylindrical lithium secondary batteries were produced, and constant current-constant voltage charge was performed until the battery voltage reached 4.2 V. After that, the batteries were left at room temperature for 24 hours, and the open circuit voltages of the batteries were measured. The batteries had open circuit voltages of 4.15 V, 4.18 V, 4.19 V, 4.15 V and 4.16 V, respectively.

### Electrode B

An electrode similar to Electrode A was produced, except that a stainless steel powder was added to the positive electrode in an amount of 0.2 mg per 100 g of the active material. Then, a saturation magnetization of 0.7×10⁻³ emu/g was output from the computing unit 2. Because the threshold value of the determination unit 3 had been set to 1.0×10⁻³ emu/g in advance, the electrode was determined as non-defective, and “non-defective” was output to the display unit 4.

Five cylindrical lithium secondary batteries similar to the above were produced by using Electrode B instead of Electrode A, and the open circuit voltages were measured under the same conditions as above. As a result, the batteries had open circuit voltages of 4.15 V, 4.11 V, 4.10 V, 4.12 V and 4.18 V, respectively.

### Electrode a

An electrode similar to Electrode A was produced, except that a nickel powder was added to the positive electrode in an amount of 1.0 mg per 100 g of the active material. Then, a saturation magnetization of 5.5×10⁻³ emu/g was output from the computing unit 2. Because the threshold value of the determination unit 3 had been set to 1.0×10⁻³ emu/g in advance, the electrode was determined as defective, and “defective” was output to the display unit 4.

Five cylindrical lithium secondary batteries similar to the above were produced by using Electrode a instead of Electrode A, and the open circuit voltages were measured under the same conditions as above. As a result, the batteries had open circuit voltages of 4.05 V, 3.95 V, 3.86 V, 4.00 V and 4.01 V, respectively.

From the foregoing, it has been confirmed that the present invention is effective in ferromagnetic impurity detection and quantification, and is capable of effectively determining whether the electrode is defective.

### INDUSTRIAL APPLICABILITY

The present invention is particularly suitable as a method for evaluating electrode materials or electrodes for use in non-aqueous electrolyte secondary batteries, but the present invention is also applicable to a method for evaluating or producing electrodes for use in batteries other than non-aqueous electrolyte secondary batteries.

1-11. (canceled)

12. A method for evaluating an electrode for a non-aqueous electrolyte secondary battery comprising the steps of:
(A) vibrating an electrode for a non-aqueous electrolyte secondary battery at a prescribed frequency successively in two or more levels of magnetic fields that have different magnetic flux densities, said electrode including a current collector and an active material layer attached to said current collector, and said active material layer including an electrode material;
(B) detecting induced magnetizations that are synchronous with said vibrations generated in said active material layer; and
(C) determining saturation magnetization of said active material layer from said induced magnetizations.

13. The evaluation method in accordance with claim 12, wherein said step A comprises vibrating said electrode in magnetic fields having magnetic flux densities that are continuously induced.

14. The evaluation method in accordance with claim 12, wherein said prescribed frequency is 65 to 95 Hz.

15. The evaluation method in accordance with claim 12, further comprising a step of comparing said saturation magnetization with a prescribed threshold value and determining said electrode as defective when said saturation magnetization exceeds said threshold value.

16. The evaluation method in accordance with claim 15, wherein said prescribed threshold value is 2.0×10⁻³ emu/g or less as a value per unit weight of said electrode material.

17. The evaluation method in accordance with claim 12, wherein said electrode material contains a composite oxide of lithium and a transition metal, and said transition metal contains at least one selected from the group consisting of Co, Ni and Mn.

18. The evaluation method in accordance with claim 17, wherein said prescribed threshold value is 1.0×10⁻³ emu/g or less as a value per unit weight of said electrode material.

19. The evaluation method in accordance with claim 12, wherein said electrode material contains at least one selected from the group consisting of a carbon material, Si and Sn.

20. A method for producing an electrode comprising the steps of:
(a) producing an electrode that includes a current collector and an active material layer attached to said current collector;
(b) vibrating said electrode at a prescribed frequency successively in two or more levels of magnetic fields that have different magnetic flux densities;
(c) detecting induced magnetizations that are synchronous with said vibrations generated in said active material layer;
(d) determining saturation magnetization of said active material layer from said induced magnetizations; and
(e) comparing said saturation magnetization with a prescribed threshold value and determining said electrode as defective when said saturation magnetization exceeds said threshold value.

21. An electrode production apparatus comprising:
a pair of magnetic poles that have primary surfaces disposed facing each other and that generate two or more levels of magnetic fields that have different magnetic flux densities;
an electrode feed section that is disposed between said pair of magnetic poles;
a vibrator that vibrates an electrode that has been introduced into said electrode feed section at a prescribed frequency, said electrode including a current collector and an active material layer attached to said current collector;
a detector that detects induced magnetizations that are synchronous with said vibrations generated in said active material layer;
a computing unit that calculates saturation magnetization of said active material layer from said induced magnetizations detected by said detector; and
a determination unit that compares said saturation magnetization with a prescribed threshold value, and determines said electrode as defective when said saturation magnetization exceeds said threshold value.
